(19) United States
(12) Patent Application Publication
(10) Pub. No.: US 2004/0264705 A1
(43) Pub. Date: Dec. 30, 2004

(54) Context aware adaptive equalization of user interface sounds

(75) Inventor: Jarmo Hiipakka, Espoo (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 10/611,035

(22) Filed: Jun. 30, 2003

(51) Int. Cl. H03B 29/00

(52) U.S. Cl. 381/71.1; 381/57

(57) ABSTRACT

In one aspect this invention provides a method to operate a mobile device that generates at least one user interaction sound, and in another aspect provides a mobile device (10) that operates in accordance with the method. The method includes determining or estimating the frequency content of a background noise signal; designing an audio filter (20) according to the determined spectral content of the background noise, and according to a spectral content of the user interaction sound; and filtering the user interaction sound using the designed audio filter so as to selectively at least one of amplify or attenuate at least one portion of the spectral content of the user interaction sound in order to maintain at least the audibility of the user interaction sound.

### TECHNICAL FIELD

This invention relates generally to portable communication apparatus and terminals, such as cellular telephones and other mobile devices and, more specifically, relates to audio context aware devices, i.e., devices that have at least one microphone that can be used to provide information about the aural surroundings or environment of the device and, even more specifically, relates to the audibility in such devices of user interaction sounds, such as ringing tones or alert sounds.

### BACKGROUND

When the user of a mobile device moves from a quiet environment into a noisier environment, the audibility of user interaction sounds, also referred to as user interface (UI) sounds, such as a ringing tone, cannot be guaranteed. Typically, some type of manual interaction is required to boost the volume of the user interaction sounds. For example, in at least one type of mobile device a user profile exists, referred to as “Outdoors”, that can be used for quickly changing the volume of user interaction sounds.

As an example, in commonly assigned U.S. Pat. No. 5,479,476, Andrea Finke-Anlauff describes a mobile telephone that has a plurality of user adjustable operating characteristics, such as the volume of an output signal, the ringing volume, and the generation of tones. When moving from one environment to another, such as from an indoor environment to an in-car environment or to an outdoor environment, it is preferable to modify a plurality of these operating characteristics. In order to facilitate the modification of the plurality of user adjustable characteristics each group includes predetermined values for all these characteristics, and the selection of a particular group results in a plurality of characteristics being modified simultaneously. Thus, when moving from one environment to another, a user is only required to make a single menu selection, resulting in a plurality of operating characteristics being modified simultaneously. For example, when moving into an in-car environment, the output volume can be increased, ringing tone volume can be increased and a call transfer function, if previously selected, can be disabled.

As a further example, in commonly assigned U.S. Pat. No. 6,463,278, Kraft et al. describe a portable phone having a controller with associated storage for the storage of the setting for a plurality of functions which may be set individually by the user. The controller arranges the stored settings as groups that each define a phone mode that is selectable by the user. Each mode is associated with at least one control parameter. The controller is associated with at least one sensor for sensing the at least one control parameter, and automatically selects the phone mode in response to the sensed control parameter.

Based on the foregoing, it can be appreciated that there is a trend towards making mobile devices more aware of their surroundings. In an ideal case, such a “context aware” device would automatically change the user profile according to the actual mobile device usage situation. However, in some situations a totally automatic change to the profile may make a user feel uncomfortable for lacking control over the device. An accidental change in the profile may also cause undesired results, such as causing the device to ring unnecessarily loud in a quiet environment. One solution would be to request the user's permission before changing the profile. However, the user may find this to be an annoyance if he or she is repeatedly requested by the mobile device for permission to change the active profile.

In commonly assigned U.S. patent application Publication No.: US 2002/0006207 A1, Matero et al. describe a system and method for providing a user with information on the operation of a portable device. In the device, a tone is produced such that, due to a tone feature, the tone can be distinguished from background noise. The tone feature may be tone frequency, duration, volume or moment of time. The device may analyze background noise automatically, and based on the analysis, it adjusts at least one feature of the tone automatically such that the tone can be distinguished from the background noise, and the background noise does not mask out the tone. Alternatively, the user can adjust the tone frequency or duration in a desired way so that it can be distinguished from background noise more clearly.

While providing a good solution in many applications and environments, if the tone modification is performed by transposing the pitch, then in some cases the amount of transposition may be such that it becomes more difficult to easily recognize the desired tone or sound. One primary reason for this is that background noise typically has a wide bandwidth.

Conventionally, adaptive equalization of sound signals has been used to preserve the perceptual quality of sound in noisy environments, typically music in a vehicle.

For example, in U.S. Pat. No. 5,615,270 Miller et al. disclose a system to compensate for the noise level within a vehicle by measuring the music level and the noise level in the vehicle through the use of analog to digital conversion and adaptive digital filtering. The system includes a sensing microphone in the vehicle cabin to measure both the music and the noise. The system further includes preamplification and analog to digital (A/D) conversion of the microphone signal, A/D conversion of a stereo music signal and a pair of filters that use an adaptive algorithm, such as the Least Mean Squares (LMS) method, to extract the noise from the total cabin sound. The system further provides for an estimation of the masking effect of the noise on the music; an adaptive correction of the music loudness and, optionally, equalization to overcome the masking effect. Digital to analog (D/A) conversion of the corrected music signal is then performed, followed by transmission of the corrected music signal to the audio system.

The system of Miller et al. is used to amplify frequencies that would otherwise be lost within the background noise. On those frequencies where the noise is the loudest, additional amplification from the system is the greatest. In practice, in a typical vehicle environments the system increases the level of the bass frequencies according to the bass frequency noise level.

### SUMMARY OF THE PREFERRED EMBODIMENTS

The foregoing and other problems are overcome, and other advantages are realized, in accordance with the presently preferred embodiments of these teachings.

The use of this invention increases the audibility of user interface (UI) sounds automatically, without affecting significantly the overall loudness of the sounds. It also does not require additional audio output power as some conventional equalization methods used in, for example, vehicle environments.

This invention solves the problems present in the prior art by making the UI sounds as audible as possible, without significantly changing the overall loudness of the sounds. This is accomplished by modifying the frequency content of the UI sounds in a context aware manner.

In one aspect this invention provides a method to operate a mobile device that generates at least one user interaction sound, and in another aspect provides a mobile device that operates in accordance with the method. The method includes determining or estimating the frequency content of a background noise signal; designing an audio filter according to the determined spectral content of the background noise, and according to a spectral content of the user interaction sound; and filtering the user interaction sound using the designed audio filter so as to selectively at least one of amplify or attenuate at least one portion of the spectral content of the user interaction sound to reduce an amount of overlap with the background noise signal. The procedure preserves at least the audibility of the user interaction sound.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 is a simplified block diagram of a mobile device that is suitable for implementing this invention;

FIG. 2A is logic flow diagram of a first embodiment of a method executed by the mobile device of FIG. 1 in accordance with this invention;

FIG. 2B is logic flow diagram of a second embodiment of a method executed by the mobile device of FIG. 1 further in accordance with this invention; and

FIGS. 3A-3E are examples of frequency diagrams that are useful in explaining the operation of this invention, where FIG. 3A shows the background noise spectrum, FIG. 3B shows the user interaction noise spectrum, FIG. 3C shows both of the combined background noise and user interaction noise spectrums, FIG. 3D shows the frequency response characteristics of the user interaction sound filter, and FIG. 3E shows both of the combined background noise and the filtered user interaction noise spectrums.

### DETAILED DESCRIPTION OF THE PREFERRED EMBODIMENTS

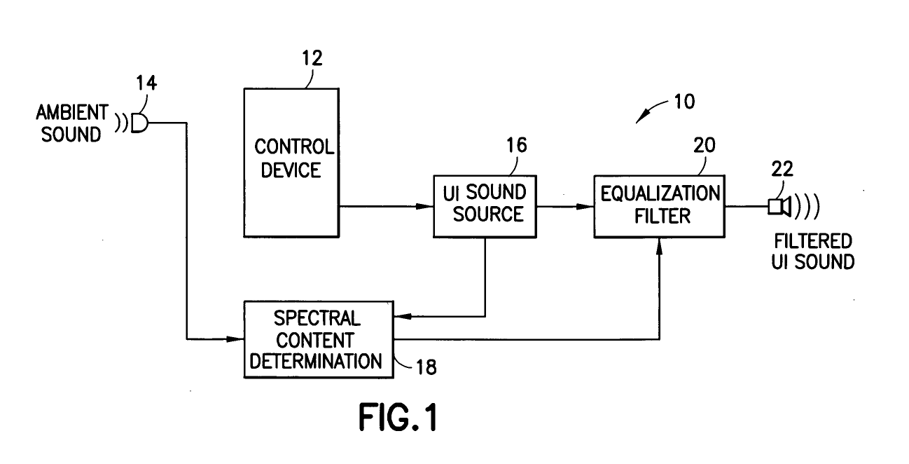

Referring to FIG. 1, a mobile device 10, such as a cellular telephone or personal communications unit, includes a control device 12, such as a general purpose microcontroller or a digital signal processor (DSP), a microphone or similar audio transducer 14 for detecting ambient or background sound (also referred to as ambient or background noise for the purposes of this invention), a source 16 of one or more desired UI sounds that are selectable by the control device 12, a unit 18 for computing the frequency content of the detected background sound and for computing the required characteristics of the desired equalization filter or filters (as a function of the spectral content of the selected UI sound), at least one audio filter 20, also referred to as an equalization filter, for modifying the spectral content of the selected UI sound, and an output transducer 22, such as a speaker, for outputting the filtered UI sound. Not shown for convenience are conventional components such as audio amplifiers, digital to analog converter(s), analog to digital converter(s) and the like, or the RF components of the mobile device 10.

It can be appreciated that the UI sound source 16 could be implemented by storing audio data in a memory device that is read out by the control device 12, or the desired UI sounds could be generated algorithmically by the control device 12. Also, all or some of the functionality of one or both of the spectral content determination block 18 and the equalization filter 20 can be implemented by a suitably programmed DSP.

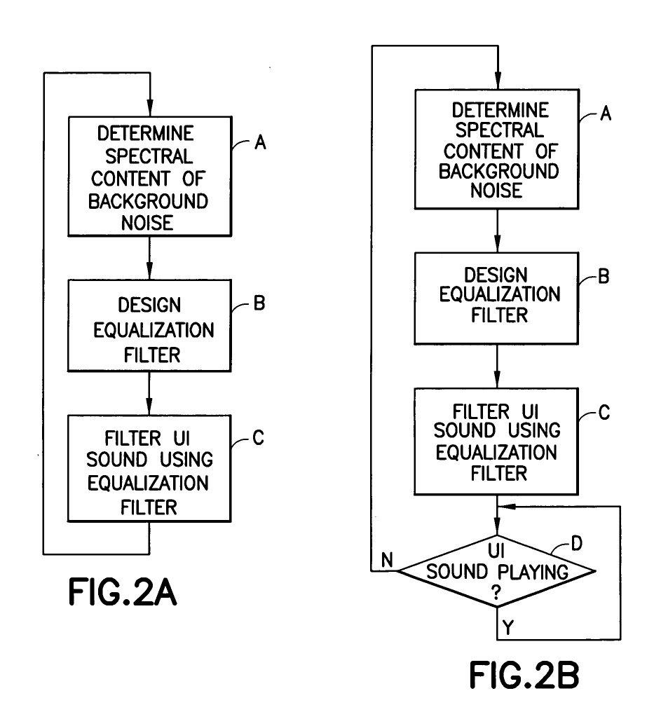

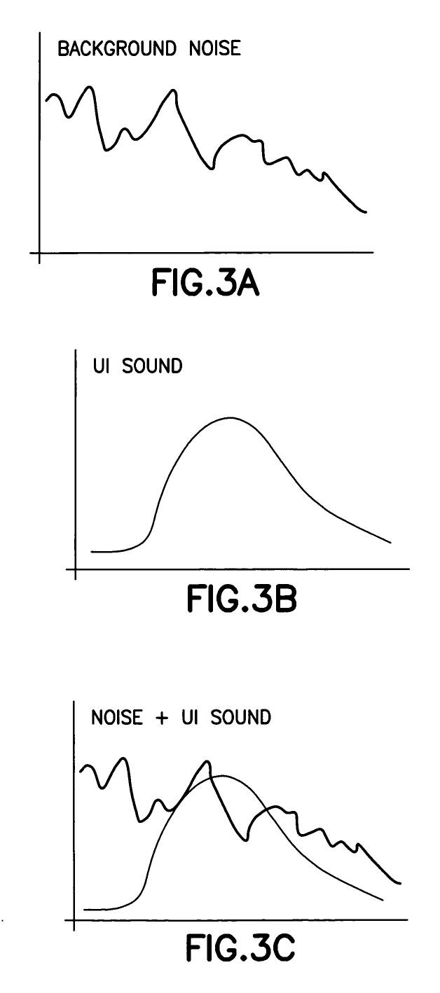

FIG. 2A shows a method of this invention, executed by the control device 12 in cooperation with the other circuitry and functions shown in FIG. 1. At Block A a calculation is performed by unit 18 to determine the frequency content of the background noise signal. At Block B there is performed the automatic design of the equalization filter(s) 20 according to the determined spectral content of the background noise, and the spectral content of the selected UI sound. The filter design information is applied to the equalization filter 20, and at Block C the equalization filter 20 filters the currently selected UI sound using the designed filter(s).

Note in FIG. 2A that the method can be recursive, i.e., it may loop at some fixed or variable interval of time to re-calculate the background noise, re-design the equalization filter 20, and then use the re-designed filter to filter the UI sound. In this manner the equalization filter 20 can be considered an adaptive filter that changes its filtering characteristics, during the time that the UI sound is generated, as the spectral content of the background noise changes.

In a most preferred embodiment of this invention, illustrated in FIG. 2B, it is advantageous to perform the filter design step only when the UI sound is not being played. In this manner, any interference caused by acoustic feedback from the UI sound to the microphone 14 is avoided. FIG. 2B thereby adds a Block D to determine whether the UI sound is being played, and loops back to again determine the spectral content of the background noise only when the UI sound is not being reproduced by the output transducer 22.

The estimation of the background noise by unit 18 can be performed using any of a number of suitable conventional methods. These include, but need not be limited to, Discrete Fourier Transform (DFT), Linear Prediction (LP), and/or sub-band filtering combined with energy estimation. The selection of a particular background noise estimation algorithm is dependent to a large measure on the optimal form of the input for a selected filter design technique.

The automatic filter design process may be performed using any of a number of suitable conventional methods. These include, but need not be limited to, inverse filtering with LP coefficients, and adaptive “graphic” equalization that is implemented, for example, either by using DFT or by using a bank of several parallel or cascaded filters.

In the filter design process, it should be noted that there may be a need to limit the applied equalization from the simple inverse filtering to a practical level. Also, it may also be desirable to provide an estimate of a suitable degree of equalization that preserves the subjective loudness of the UI sounds. One solution estimates the average frequency content of all of the possible UI sounds stored in the source 16, and then designs the equalization filter 20 such that the average loudness remains approximately constant. A more sophisticated solution takes into account the individual frequency content of the specific selected UI sound (e.g., a particular ringing tone) for achieving optimal loudness alignment.

A presently preferred technique for filtering the UI sounds in equalization filter block 20 is to utilize linear digital filters. There exist a number of algorithms for designing linear digital filters. It is also within the scope of this invention to integrate the equalization function into the sound production algorithm, e.g., during MP3 decoding or during MIDI synthesis. The equalization filter 20 may also be implemented as a non-linear filter with, for example, compression capabilities.

In all of these cases, however, the filter 20 operates so as to provide UI sounds with spectral characteristics that are less likely to be masked by the background noise.

In accordance with this invention the equalization is done in an “inverse” sense. That is, the system and method selectively amplify or attenuate at least one portion of the spectral content of the user interaction sound to reduce an amount of overlap with the background noise signal. The goal is not is not to maintain the perceptual quality of the UI sound per se, but to maintain the audibility of the UI sound. This approach may be seen to be similar to the technique utilized by singers with classical training; they shape their vocal tract to create a singer's formant that amplifies the higher frequencies. This makes it possible for the singer to make his or her voice audible over the playing of the orchestra, because the frequency content of the accompanying orchestra is typically more attenuated in the higher frequency band.

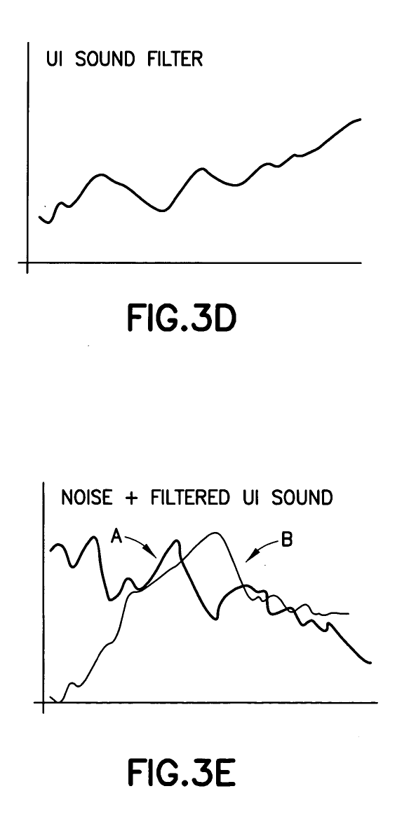

Referring to FIG. 3A, assume at time t that the spectral content of the background noise has the indicated characteristics. Referring to FIG. 3B, assume also that the desired or selected UI sound has the indicated spectral characteristics. FIG. 3C shows both of the combined background noise and the UI noise spectrums. FIG. 3D shows the frequency response characteristics of the resulting user interaction sound filter 20, and FIG. 3E shows both of the combined background noise and the filtered user interaction noise spectrums. The equalization filter 20 is designed such that the frequency portion of the UI sound at location A, that would overlap with a peak in the background noise, is attenuated, since it would not be heard anyway. In a similar manner, where the background noise is softer, such as at location B, the UI sound is amplified, so that it is more easily heard. In this manner the perceptual quality of the UI sound may be changed, but the audibility of the UI sound is not significantly impaired.

Note that this process differs from the process disclosed in the above-referenced commonly assigned U.S. patent application Publication No.: US 2002/0006207 A1 to Matero et al., in that the UI sound frequency is not generated in a different frequency range than the frequency range where background sound is detected, but instead the UI sound frequency is modified so as to accommodate the underlying spectral characteristics of the background sound.

Based on the foregoing description it should also be apparent that this invention pertains as well to, and also encompasses, a computer program that is embodied on or in a computer readable medium for directing operation of a data processor, such as the control device 12, of a portable communication device, such as the mobile device 10. The computer program causes the data processor to determine the frequency content of a background noise signal (18) and to provide the audio filter (20) according to the determined spectral content of the background noise, and according to a spectral content of the user interaction sound (16), to selectively at least one of amplify or attenuate at least one portion of the spectral content of the user interaction sound in order to maintain at least the audibility of the user interaction sound.

As non-limiting examples, the frequency content of the background noise signal may be determined in accordance with at least one of the DFT procedure, the Linear Prediction procedure and the sub-band filtering procedure that uses energy estimation. Preferably, the frequency content of the background noise signal is determined during a time when a user interaction sound is not being generated.

The audio filter 20 may employ, as examples, inverse filtering with Linear Prediction (LP) coefficients, or it may employ the graphic equalization technique implemented using one of a DFT procedure or a bank of parallel or cascaded filters.

The foregoing description has provided by way of exemplary and non-limiting examples a full and informative description of the best method and apparatus presently contemplated by the inventor for carrying out the invention. However, various modifications and adaptations may become apparent to those skilled in the relevant arts in view of the foregoing description, when read in conjunction with the accompanying drawings and the appended claims. As but some examples, the use of other similar or equivalent background noise characterization algorithms, filter design algorithms, and types of filters may be attempted by those skilled in the art. However, all such and similar modifications of the teachings of this invention will still fall within the scope of this invention. Further, while the method and apparatus described herein are provided with a certain degree of specificity, the present invention could be implemented with either greater or lesser specificity, depending on the needs of the user. Further, some of the features of the present invention could be used to advantage without the corresponding use of other features. As such, the foregoing description should be considered as merely illustrative of the principles of the present invention, and not in limitation thereof, as this invention is defined by the claims which follow.

What is claimed is:

1. A method to operate a mobile device that generates at least one user interaction sound, comprising:
determining the frequency content of a background noise signal;
designing an audio filter according to the determined spectral content of the background noise, and according to a spectral content of the user interaction sound; and
filtering the user interaction sound using the designed audio filter so as to selectively at least one of amplify or attenuate at least one portion of the spectral content of the user interaction sound in order to maintain at least the audibility of the user interaction sound.

2. A method as in claim 1, where determining the frequency content of the background noise signal uses at least one of a Discrete Fourier Transform (DFT) procedure and a Linear Prediction (LP) procedure.

3. A method as in claim 1, where determining the frequency content of the background noise signal occurs at a time when a user interaction sound is not being generated.

4. A method as in claim 1, where determining the frequency content of the background noise signal uses a sub-band filtering procedure combined with energy estimation.

5. A method as in claim 1, where designing the audio filter designs a filter that uses inverse filtering with Linear Prediction (LP) coefficients.

6. A method as in claim 1, where designing the audio filter designs a filter that uses adaptive graphic equalization.

7. A method as in claim 1, where designing the audio filter designs a filter that maintains an average loudness of a plurality of user interaction sounds approximately constant.

8. A method as in claim 1, where designing the audio filter designs a filter that maintains a loudness of a particular user interaction sound approximately constant.

9. A method as in claim 1, where designing the audio filter designs one of a linear digital filter or a non-linear digital filter.

10. A method as in claim 1, where designing the audio filter designs a non-linear digital filter with compression capabilities.

11. A method as in claim 1, where designing the audio filter designs a filter for integration into a sound production algorithm.

12. A mobile device that generates at least one user interaction sound, comprising:
means for determining the frequency content of a background noise signal; and
means for designing an audio filter according to the determined spectral content of the background noise, and according to a spectral content of the user interaction sound, where the audio filter filters the user interaction sound so as to selectively at least one of amplify or attenuate at least one portion of the spectral content of the user interaction sound in order to maintain at least the audibility of the user interaction sound.

13. A mobile device as in claim 12, where said means for determining the frequency content of the background noise signal uses at least one of a Discrete Fourier Transform (DFT) procedure and a Linear Prediction (LP) procedure.

14. A mobile device as in claim 12, where said means for determining the frequency content of the background noise signal operates during a time when a user interaction sound is not being generated.

15. A mobile device as in claim 12, where said means for determining the frequency content of the background noise signal uses a sub-band filtering procedure combined with energy estimation.

16. A mobile device as in claim 12, where said means for designing the audio filter designs a filter that uses inverse filtering with Linear Prediction (LP) coefficients.

17. A mobile device as in claim 12, where said means for designing the audio filter designs a filter that uses adaptive graphic equalization.

18. A mobile device as in claim 12, where said means for designing the audio filter designs a filter that maintains an average loudness of a plurality of user interaction sounds approximately constant.

19. A mobile device as in claim 12, where said means for designing the audio filter designs a filter that maintains a loudness of a particular user interaction sound approximately constant.

20. A mobile device as in claim 12, where said means for designing the audio filter designs one of a linear digital filter or a non-linear digital filter.

21. A mobile device as in claim 12, where said means for designing the audio filter designs a non-linear digital filter with compression capabilities.

22. A mobile device as in claim 12, where said means for designing the audio filter designs a filter for integration into a sound production algorithm.

23. A computer program embodied on or in a computer readable medium for directing operation of a data processor of a portable communication device to determine the frequency content of a background noise signal and to provide an audio filter according to the determined spectral content of the background noise, and according to a spectral content of the user interaction sound, to selectively at least one of amplify or attenuate at least one portion of the spectral content of the user interaction sound in order to maintain at least the audibility of the user interaction sound.

24. A computer program as in claim 23, where the frequency content of the background noise signal is determined in accordance with at least one of a Discrete Fourier Transform (DFT) procedure, a Linear Prediction (LP) procedure and a sub-band filtering procedure that uses energy estimation.

25. A computer program as in claim 23, where the frequency content of the background noise signal is determined during a time when a user interaction sound is not being generated.

26. A computer program as in claim 23, where said audio filter employs inverse filtering with Linear Prediction (LP) coefficient.

27. A computer program as in claim 23, where said audio filter employs adaptive graphic equalization implemented using one of a Discrete Fourier Transform (DFT) procedure and a a bank of parallel or cascaded filters.
